(19) United States
(12) Patent Application Publication
(10) Pub. No.: US 2013/0315005 A1
(43) Pub. Date: Nov. 28, 2013

(54) INPUT BUFFER

(71) Applicant: SAMSUNG ELECTRONICS CO., LTD, Suwon-si (KR)

(72) Inventor: Yunseok YANG, Hwaseong-si (KR)

(73) Assignee: Samsung Electronics Co., Ltd, Suwon-si (KR)

(21) Appl. No.: 13/834,641

(22) Filed: Mar. 15, 2013

(30) Foreign Application Priority Data
May 22, 2012 (KR) 10-2012-0054322

(51) Int. Cl. H03K 19/003; G11C 7/10

(52) U.S. Cl. CPC H03K 19/00384; G11C 7/1084
USPC 365/189.05; 326/32

(57) ABSTRACT

An input buffer which includes an amplification circuit configured to amplify a difference between a first input signal and a second input signal; and an inverter configured to invert an output signal of the amplification circuit. The amplification circuit provides the inverter with a bias voltage generated on the basis of one of the first and second input signals, and the inverter operates responsive to the bias voltage.

### CROSS-REFERENCE TO RELATED APPLICATIONS

A claim for priority under 35 U.S.C. §119 is made to Korean Patent Application No. 10-2012-0054322 filed May 22, 2012, in the Korean Intellectual Property Office, the entire contents of which are hereby incorporated by reference.

### BACKGROUND OF THE INVENTION

1. Field of the Invention

The inventive concepts described herein relate to an input buffer, and more particularly, relate to an input buffer capable of controlling a variation in an output characteristic due to process, voltage, and temperature (hereinafter, referred to as PVT) variations.

2. Description of the Related Art

A semiconductor chip may be mounted on a printed circuit board (PCB) substrate, and may perform given logics and functions when it is supplied with an appropriate driving voltage. The semiconductor chip may be provided with an external signal to perform the given logics and functions. The external signal may be buffered through an input buffer of the semiconductor chip.

A conventional input buffer may be a static input buffer. The static input buffer may be formed of an inverter which includes PMOS and NMOS transistors connected in series between a power supply voltage and a ground voltage. The static buffer may have the merit of being simple in structure. However, since the static buffer is weak against noise, it may be difficult to apply the static buffer to a semiconductor chip which necessitates an input signal having a small swing magnitude and a high operating frequency. For this reason, a differential amplifier type input buffer that is more tolerable to noise may be applied to a semiconductor chip which necessitates an input signal having a small swing magnitude and a high operating frequency.

Since the differential amplifier type input buffer is formed of a general differential amplifier circuit and an inverter, however, output characteristics of components of the differential amplifier type input buffer may vary due to PVT variations.

### SUMMARY OF THE INVENTION

Exemplary embodiments of the inventive concept provide an input buffer which comprises an amplification circuit configured to amplify a difference between a first input signal and a second input signal; and an inverter configured to invert an output signal of the amplification circuit, wherein the amplification circuit provides the inverter with a bias voltage generated on the basis of one of the first and second input signals, and the inverter operates responsive to the bias voltage.

Exemplary embodiments of the inventive concept also provide an input buffer comprising an amplification circuit configured to generate a bias voltage on the basis of a first input signal or a second input signal and to amplify a difference between the first input signal and the second input signal; and an inverter configured to invert an output signal of the amplification circuit in response to the bias voltage provided from the amplification circuit, wherein the inverter includes pull-up and pull-down control units enabling the inverter in response to the bias voltage.

An exemplary embodiment of the general inventive concept also provides an input buffer comprising: an amplification circuit configured to amplify a difference between a first input signal and a second input signal; and an inverter configured to invert an output signal of the amplification circuit, wherein the amplification circuit and the inverter are further configured to use a bias current having the same magnitude as a driving current.

In an exemplary embodiment, the amplification circuit comprises: a constant current source which provides the bias current; and an amplification unit which amplifies a difference between the first input signal and the second input signal.

In an exemplary embodiment, the amplification unit comprises: a first PMOS transistor having a source connected with a power supply voltage, a gate, and a drain; a second PMOS transistor having a source connected with the power supply voltage, a gate, and a drain, the first and second PMOS transistors forming a current mirror; a first NMOS transistor having a drain connected with the drain and gate of the first PMOS transistor, a gate connected to receive the first input signal, and a source connected with the constant current source; and a second NMOS transistor having a drain connected with the drain of the second PMOS transistor, a gate connected to receive the second input signal, and a source connected with the constant current source.

In an exemplary embodiment, the constant current source comprises: a third NMOS transistor having a drain connected with the drains of the first and second NMOS transistor, a gate connected to receive the bias voltage, and a source grounded.

In an exemplary embodiment, the inverter comprises: a third PMOS transistor having a source connected with the power supply voltage, a gate connected to receive an output signal of the amplification circuit, and a drain; a fourth NMOS transistor having a drain connected with the drain of the third PMOS transistor, a gate connected to receive the output signal of the amplification circuit, and a source; and a fifth NMOS transistor having a drain connected with the source of the fourth NMOS transistor, a gate connected to receive the bias voltage, and a source grounded.

Additional features and utilities of the present general inventive concept will be set forth in part in the description which follows and, in part, will be obvious from the description, or may be learned by practice of the general inventive concept.

### BRIEF DESCRIPTION OF THE DRAWINGS

The above and other features and utilities of the inventive concept will become apparent from the following description with reference to the following figures, of which:

FIG. 1 is a block diagram schematically illustrating an input buffer according to an embodiment of the inventive concept.

FIG. 2 is a circuit diagram illustrating an input buffer in FIG. 1.

FIG. 3 is a circuit diagram illustrating an input buffer according to another embodiment of the inventive concept.

FIG. 4 is a circuit diagram illustrating an input buffer according to still another embodiment of the inventive concept.

FIG. 5 is a block diagram schematically illustrating a semiconductor memory system according to an embodiment of the inventive concept.

FIG. 6 is a block diagram schematically illustrating an electronic device according to an embodiment of the inventive concept.

### DETAILED DESCRIPTION OF THE PREFERRED EMBODIMENTS

Exemplary embodiments of the inventive concept will be described in detail with reference to the accompanying drawings. The inventive concept, however, may be embodied in various different forms, and should not be construed as being limited only to the illustrated embodiments. Rather, these exemplary embodiments are provided as examples so that this disclosure will be thorough and complete, and will fully convey the concept of the inventive concept to those skilled in the art. Accordingly, known processes, elements, and techniques are not described with respect to some of the embodiments of the inventive concept. Unless otherwise noted, like reference numerals denote like elements throughout the attached drawings and written description, and thus descriptions will not be repeated. In the drawings, the sizes and relative sizes of layers and regions may be exaggerated for clarity.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

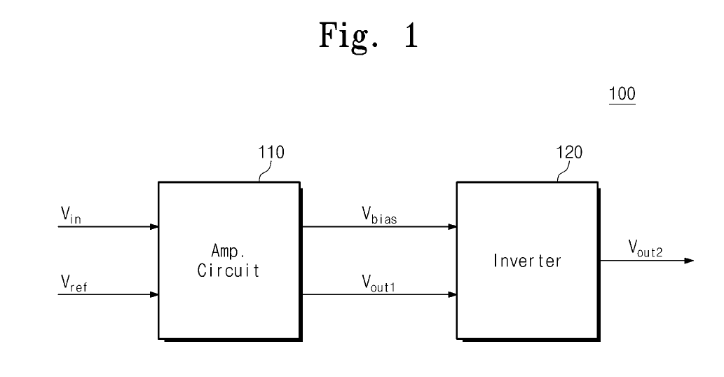

FIG. 1 is a block diagram schematically illustrating an input buffer according to an exemplary embodiment of the inventive concept.

Referring to FIG. 1, an input buffer 100 according to an embodiment of the inventive concept may include an amplification circuit 110 and an inverter 120.

The amplification circuit 110 may amplify a difference between a first input signal V_{ref} and a second input signal V. The first input signal V_{ref} may be a reference voltage having a constant voltage level. The amplification circuit 110 may generate a bias voltage V_{bias} using the first input signal V_{ref} in a self-biasing manner. The amplification circuit 110 may be driven by a bias current generated on the basis of the bias voltage V_{bias}. That is, the amplification circuit 110 may amplify a difference between the first input signal V_{ref} and the second input signal Vᵢₙ in response to the bias voltage V_{bias}.

The inverter 120 may operate responsive to the bias voltage V_{bias} provided from the amplification circuit 110. The inverter 120 may invert an output signal Vₒᵤₜ₁ from the amplification circuit 110 in response to the bias voltage V_{bias}.

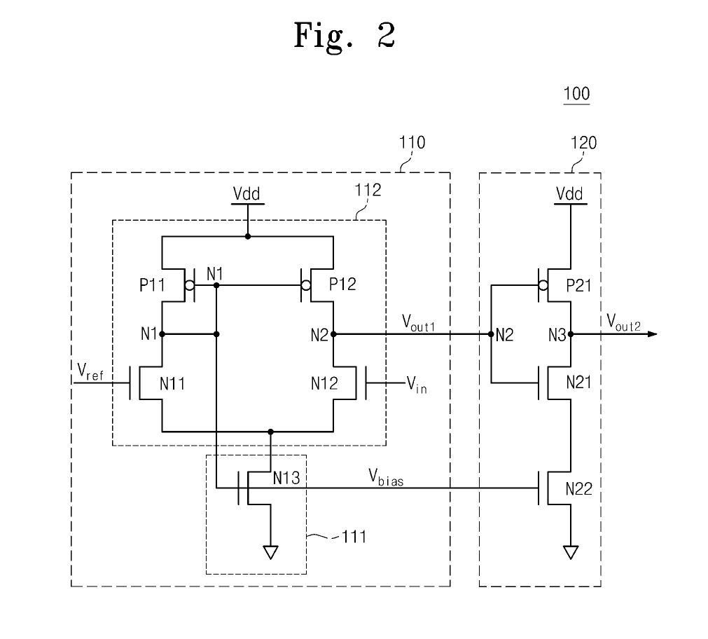

As described above, the amplification circuit 110 may provide the bias voltage V_{bias} to the inverter 120. Variations in output characteristics of the amplification circuit 110 and the inverter 120 due to PVT variations may be controlled to be identical to each other. In detail, since the amplification circuit 110 and the inverter 120 operate responsive to the bias voltage V_{bias}, a duty cycle of an output signal Vₒᵤₜ₂ may be maintained constantly. This will be more fully described with reference to FIGS. 2 to 4.

FIG. 2 is a circuit diagram illustrating an input buffer in FIG. 1.

Referring to FIG. 2, an input buffer 100 may include an amplification circuit 110 and an inverter 120.

The amplification circuit 110 may include a constant current source 111 and an amplification unit 112. The constant current source 111 may be formed of an NMOS transistor N13 which operates in response to a bias voltage V_{bias} provided to its gate. However, the inventive concept is not limited thereto. The NMOS transistor (hereinafter, referred to as a third NMOS transistor) N13 may have a drain connected with sources of NMOS transistors N11 and N12 ((hereinafter, referred to as first and second NMOS transistors) and a gate connected to receive the bias voltage V_{bias}.

The amplification unit 112 may include first and second PMOS transistors P11 and P12 and the first and second NMOS transistors N11 and N12. The first and second PMOS transistors P11 and P12 may form a current mirror by connecting their sources to a power supply voltage Vdd and interconnecting their gates. The first NMOS transistor N11 may have a drain connected with the drain and gate of the first PMOS transistor P11 and a gate connected to input a first input signal V_{ref}. The second NMOS transistor N12 may have a drain connected with the drain of the second PMOS transistor P12 and a gate connected to input a second input signal Vᵢₙ.

The gate of the third NMOS transistor N13 and the gates of the first and second PMOS transistors P11 and P12 may be connected in common to form a node N1. The drain of the second PMOS transistor P12 and the drain of the second NMOS transistor N12 may be interconnected to form a node N2. An output signal Vout1 of the amplification circuit 110 may be output to the inverter 120 via the node N2.

The inverter 120 may include a third PMOS transistor P21, a fourth NMOS transistor N21, and a fifth NMOS transistor N22. The third PMOS transistor P21 may have a source connected with the power supply voltage Vdd and a gate connected to receive the output signal Vₒᵤₜ₁. The fourth NMOS transistor N21 may have a drain connected with a drain of the third PMOS transistor P21 and a gate connected to receive the output signal Vₒᵤₜ₁. The fifth NMOS transistor N22 may have a drain connected with a source of the fourth NMOS transistor N21 and a gate connected with the gate of the third NMOS transistor N13 of the amplification unit 110. The bias voltage V_{bias} may be provided to the gate of the fifth NMOS transistor N22 from the node N1. The gates of the PMOS and NMOS transistors P21 and N21 may be connected in common with the node N2. The drains of the PMOS and NMOS transistors P21 and N21 may be connected in common to form a node N3. An output signal Vₒᵤₜ₂ may be output via the node N3.

Below, an operation of the input buffer 100 will be described. The amplification circuit 110 may generate the bias voltage V_{bias} using the first input signal V_{ref} in a self-biasing method. The drains of the NMOS and PMOS transistors N11 and P11 may be interconnected to provide the bias voltage V_{bias} to the gate of the third NMOS transistor N13. The amplification circuit 110 may be driven by a bias current generated on the basis of the bias voltage V_{bias}.

That is, the amplification unit 112 may amplify a difference between the first input signal V_{ref} and the second input signal V. In a case where a level of the second input signal Vᵢₙ is lower than a level of the first input signal V_{ref}, the output signal Vout1 may have a logically high level. In a case where a level of the second input signal Vᵢₙ is higher than a level of the first input signal V_{ref}, the output signal Vₒᵤₜ₁ may have a logically low level. The output signal Vₒᵤₜ₁ may be provided to the inverter 120.

The inverter 120 may invert the output signal Vₒᵤₜ₁ in response to the bias voltage V_{bias}. When the output signal Vₒᵤₜ₁ has a logically low level, the third PMOS transistor P21 may be turned on and the fourth NMOS transistor N21 may be turned off. In this case, the output signal Vₒᵤₜ₂ may have a logically high level. When the output signal Vₒᵤₜ₁ has a logically high level, the third PMOS transistor P21 may be turned off and the fourth NMOS transistor N21 may be turned on. In this case, the output signal Vₒᵤₜ₂ may have a logically low level.

As a result, if a level of the second input signal Vᵢₙ is lower than a level of the first output signal V_{ref}, the output signal Vₒᵤₜ₂ of the input buffer 100 may have a logically low level. If a level of the second input signal Vᵢₙ is higher than a level of the first output signal V_{ref}, the output signal Vₒᵤₜ₂ of the input buffer 100 may have a logically high level.

The bias voltage V_{bias} generated at the amplification circuit 110 may be provided to the gates of the NMOS transistors N13 and N22. The NMOS transistors N13 and N22 may act as a constant current source. That is, the NMOS transistors N13 and N22 may generate the same amount of bias current in response to the bias voltage V_{bias}. The amplification circuit 110 and the inverter 120 may be configured to use a bias current having the same magnitude as a driving current, and characteristics thereof may be varied identically at PVT variations. That is, a duty cycle of the output signal Vₒᵤₜ₂ of the inverter 120 may be maintained constantly.

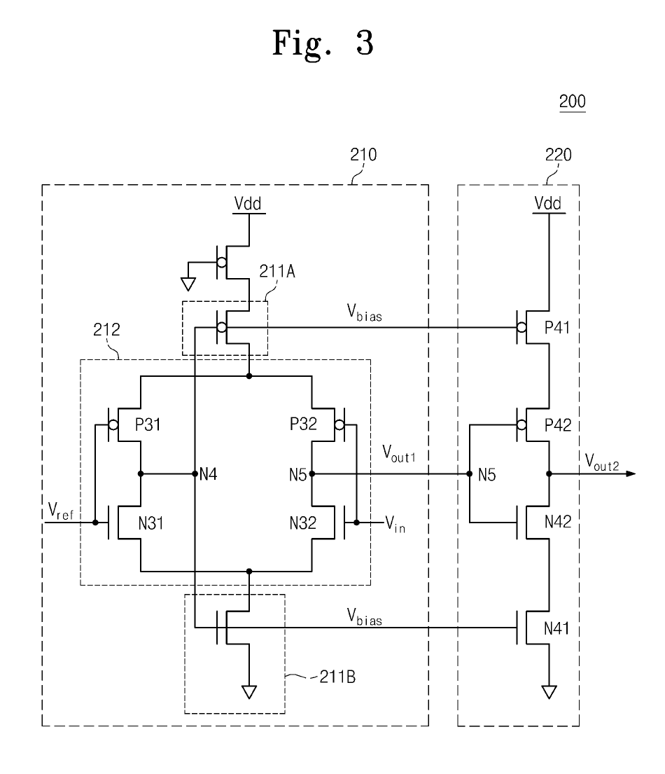

FIG. 3 is a circuit diagram illustrating an input buffer according to another embodiment of the inventive cocept.

Referring to FIG. 3, an input buffer 200 may include an amplification circuit 210 and an inverter 220. The amplification circuit 210 may include a first constant current source 211A, a second constant current source 211B, and a amplification unit 212.

The first constant current source 211A may be formed of a PMOS transistor, for example. The first constant current source 211A may be connected with a power supply voltage Vdd via a switch. The switch may be formed of an NMOS transistor or a PMOS transistor. The second constant current source 211 B may be formed of an NMOS transistor, for example. Gates of the first and second constant current sources 211A and 211B may be interconnected to form a node N4. Below, there may be described an example that the first constant current source 211A is formed of a PMOS transistor and the second constant current source 211B is formed of an NMOS transistor. However, the inventive concept is not limited thereto.

The amplification unit 212 may include a pair of MOS transistors P31 and N31 driven by a first input signal V_{ref} and a pair of MOS transistors P32 and N32 driven by a second input signal Vᵢₙ. The fourth PMOS transistor P31 may have a source connected with the first constant current source 211A and a gate connected to receive the first input signal V_{ref}. The fifth PMOS transistor P32 may have a source connected with the first constant current source 211A and a gate connected to receive the second input signal Vᵢₙ. The sixth NMOS transistor N31 may have a drain connected with a drain of the fourth PMOS transistor P31 and a gate connected to receive the first input signal V_{ref}. The seventh NMOS transistor N32 may have a drain connected with a drain of the fifth PMOS transistor P32 and a gate connected to receive the second input signal Vᵢₙ.

The drains of the PMOS and NMOS transistors P31 and N31 may be connected with the first and second constant current sources 211A and 211B via the node N4.

The inverter 220 may include a pull-up control unit P41 for increasing a level of an output signal Vₒᵤₜ₂ and a pull-down control unit N41 for decreasing a level of the output signal Vₒᵤₜ₂. In example embodiments, the pull-up control unit P41 may be formed of a PMOS transistor and the pull-down control unit N41 may be formed of an NMOS transistor. However, the inventive concept is not limited thereto.

As the pull-up control unit, the sixth PMOS transistor P41 may have a source connected with a power supply voltage Vdd and a gate connected with a gate of the first constant current source 211A. A seventh PMOS transistor P42 may have a source connected with a drain of the sixth PMOS transistor P41 and a gate connected to receive the output signal Vₒᵤₜ₁. An eighth NMOS transistor N42 may have a drain connected with a drain of the seventh PMOS transistor P42 and a gate connected to receive the output signal Vₒᵤₜ₁. A ninth NMOS transistor N41 may have a drain connected with a source of the eighth NMOS transistor N42 and a gate connected with a gate of the second constant current source 211B.

Below, an operation of the input buffer 200 will be more fully described. The first and second constant current sources 211A and 211 B may generate bias currents in response to the bias voltage V_{bias} generated according to the first input signal V_{ref}. The first input signal V_{ref} may be a reference voltage having a constant voltage level. The drains of the PMOS and NMOS transistors P31 and N31 may be interconnected to provide a bias voltage to the first and second constant current sources 211A and 211B.

The amplification unit 212 may amplify a difference between the first input signal V_{ref} and the second input signal Vᵢₙ using the bias current generated by the first and second constant current sources 211A and 211B as a driving current. That is, the amplification unit 212 may differentially amplify the first input signal V_{ref} and the second input signal V.

The output signal Vₒᵤₜ₁ of the amplification unit 212 may be provided to the inverter 220. The inverter 220 may invert the output signal Vₒᵤₜ₁ in response to the bias voltage V_{bias}. In detail, when the output signal Vₒᵤₜ₁ has a logically low level, the seventh PMOS transistor P42 may be turned on and the eighth NMOS transistor N42 may be turned off. In this case, the output signal Vₒᵤₜ₂ may have a logically high level. When the output signal Vₒᵤₜ₁ has a logically high level, the seventh PMOS transistor P42 may be turned off and the eighth NMOS transistor N42 may be turned on. In this case, the output signal Vₒᵤₜ₂ may have a logically low level.

As a result, if a level of the second input signal Vᵢₙ is lower than a level of the first input signal V_{ref}, the output signal Vₒᵤₜ₂ of the input buffer 100 may have a logically low level. On the other hand, if a level of the second input signal Vᵢₙ is higher than a level of the first input signal V_{ref}, the output signal Vₒᵤₜ₂ of the input buffer 100 may have a logically high level.

The gates of the PMOS and NMOS transistors P42 and N42 may be interconnected to form a node N5. The bias voltage V_{bias} may be provided to the gate of the sixth PMOS transistor P41 from the node N4. The bias voltage V_{bias} may be provided to the gate of the ninth NMOS transistor N41 from the node N4. The transistors P41 and N41 may act as a constant current source. That is, the sixth PMOS transistor P41 may generate a bias current having the same magnitude as the first constant current source 211A. The ninth NMOS transistor N41 may generate a bias current having the same magnitude as the second constant current source 211B.

The amplification circuit 210 and the inverter 220 may be configured to use a bias current having the same magnitude as a driving current, and characteristics thereof may be varied identically at PVT variations. That is, a duty cycle of the output signal Vₒᵤₜ₂ of the inverter 220 may be maintained constantly.

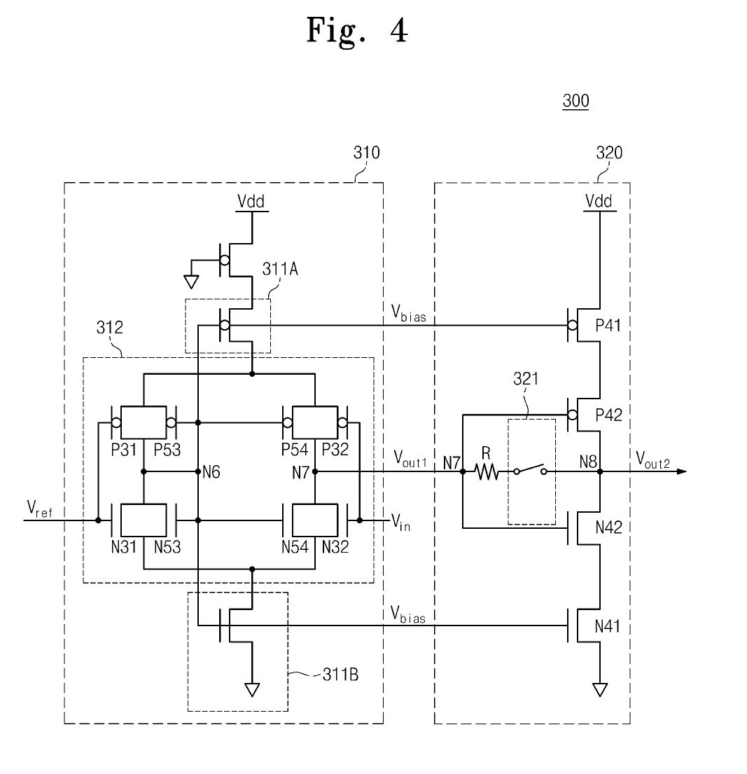

FIG. 4 is a circuit diagram illustrating an input buffer according to still another embodiment of the inventive concepts. In FIG. 4, constituent elements that are identical to those in FIG. 3 may be marked by the same reference numerals.

Referring to FIG. 4, an input buffer 300 may include a first constant current source 311A, a second constant current source 311 B, and an amplification unit 312.

The first constant current source 311A may be formed of a PMOS transistor, for example. The first constant current source 311A may be connected with a power supply voltage Vdd via a switch. The switch may be formed of an NMOS transistor or a PMOS transistor. The second constant current source 311B may be formed of an NMOS transistor, for example. Gates of the first and second constant current sources 311A and 311B may be interconnected to form a node N6. Below, there may be described an example that the first constant current source 311A is formed of a PMOS transistor and the second constant current source 311B is formed of an NMOS transistor. However, the inventive concept is not limited thereto.

The amplification unit 312 may include a fourth PMOS transistor P31, a fifth PMOS transistor P32, a sixth NMOS transistor N31, and a seventh NMOS transistor N32. The fourth PMOS transistor P31 may have a source connected with the first constant current source 311A and a gate connected to receive the first input signal V_{ref}. The fifth PMOS transistor P32 may have a source connected with the first constant current source 311A and a gate connected to receive the second input signal Vᵢₙ. The sixth NMOS transistor N31 may have a drain connected with a drain of the fourth PMOS transistor P31 and a gate connected to receive the first input signal V_{ref}. The seventh NMOS transistor N32 may have a drain connected with a drain of the fifth PMOS transistor P32 and a gate connected to receive the second input signal Vᵢₙ. The source of the transistors N31 and N32 may be connected with the second constant current source 311B.

The amplification unit 312 may further comprise an eighth PMOS transistor P53, a ninth PMOS transistor P54, a tenth NMOS transistor N53, and an eleventh NMOS transistor N54. The eighth PMOS transistor P53 may have a source connected with a drain of the first constant current source 311A and a gate connected with a drain of the fourth PMOS transistor P31. The ninth PMOS transistor P54 may have a source connected with the drain of the first constant current source 311A. The tenth NMOS transistor N53 may have a source connected with the drain of the second constant current source 311B and a gate connected with the drain of the sixth NMOS transistor N31. The eleventh NMOS transistor N54 may have a source connected with the second constant current source 311B.

The drains of the PMOS and NMOS transistors P31 and N31 may be connected with the first and second constant current sources 311A and 311B via the node N6. The gates of the eighth and ninth PMOS transistors P53 and P54 may be connected with the node N6. The gates of the tenth and eleventh NMOS transistors N53 and N54 may be connected with the node N6.

The inverter 320 may include a sixth PMOS transistor P41, a seventh PMOS transistor P42, an eighth NMOS transistor N42, and a ninth NMOS transistor N41. The sixth PMOS transistor P41 may have a source connected with a power supply voltage Vdd and a gate connected with a gate of the first constant current source 311A. The seventh PMOS transistor P42 may have a source connected with a drain of the sixth PMOS transistor P41 and a gate connected to receive the output signal Vₒᵤₜ₁. The eighth NMOS transistor N42 may have a drain connected with a drain of the seventh PMOS transistor P42 and a gate connected to receive the output signal Vₒᵤₜ₁. The ninth NMOS transistor N41 may have a drain connected with a source of the eighth NMOS transistor N42 and a gate connected with a gate of the second constant current source 311B.

The gates of the PMOS and NMOS transistors P42 and N42 may be interconnected to form a node N7. The drains of the PMOS and NMOS transistors P42 and N42 may be interconnected to form a node N8.

The inverter 320 may further include a resistor R and a switch 321 which are connected between the nodes N7 and N8. The switch 321 may be formed of a PMOS transistor or an NMOS transistor, for example. The switch 321 may be controlled by a signal which is provided from an external device. For example, the switch 321 may be turned on or off by a signal which is provided from a device (e.g., formed of well-known DIP-switches) adjustable by a user.

Below, an operation of the input buffer 300 will be more fully described. The first and second constant current sources 311A and 311B may generate bias currents in response to the bias voltage V_{bias} generated according to the first input signal V_{ref}. The first input signal V_{ref} may be a reference voltage having a constant voltage level. The amplification unit 312 may amplify a different between the first input signal V_{ref} and the second input signal Vᵢₙ using the bias current generated by the first and second constant current sources 311A and 311B as a driving current. That is, the amplification unit 312 may differentially amplify the first input signal V_{ref} and the second input signal Vᵢₙ.

The bias voltages V_{bias} may be provided to the transistors P53, P54, N53, and N54. The transistors P53, P54, N53, and N54 may perform a negative feedback operation on the bias voltage V_{bias}. Thus a swing magnitude of the bias voltage V_{bias} may be reduced more than that described with reference to FIG. 3.

The output signal Vₒᵤₜ₁ of the amplification unit 312 may be provided to the inverter 320. The inverter 320 may invert the output signal Vₒᵤₜ₁ in response to the bias voltage V_{bias}. In detail, when the output signal Vₒᵤₜ₁ has a logically low level, the seventh PMOS transistor P42 may be turned on and the eighth NMOS transistor N42 may be turned off. Thus, the output signal Vₒᵤₜ₂ may have a logically high level. On the other hand, when the output signal Vₒᵤₜ₁ has a logically high level, the seventh PMOS transistor P42 may be turned off and the eighth NMOS transistor N42 may be turned on. Thus, the output signal Vₒᵤₜ₂ may have a logically low level.

As a result, in case that a level of the second input signal Vᵢₙ is lower than a level of the first input signal V_{ref}, the output signal Vₒᵤₜ₂ of the input buffer 300 may have a logically low level. On the other hand, if a level of the second input signal Vᵢₙ is higher than a level of the first input signal V_{ref}, the output signal Vₒᵤₜ₂ of the input buffer 300 may have a logically high level. When the switch 321 is turned on, a swing magnitude of the output signal Vout2 may be reduced more than that described with reference to FIG. 3. The reason may be that a voltage drop arises at the node N8 via the resistor R.

The bias voltage V_{bias} may be provided to the gate of the sixth PMOS transistor P41 from the node N6. The bias voltage V_{bias} may be provided to the gate of the ninth NMOS transistor N41 from the node N6. The transistors P41 and N41 may act as a constant current source. That is, the sixth PMOS transistor P41 may generate a bias current having the same magnitude as the first constant current source 311A. The ninth NMOS transistor N41 may generate a bias current having the same magnitude as the second constant current source 311B.

The amplification circuit 310 and the inverter 320 may be configured to use a bias current having the same magnitude as a driving current, and characteristics thereof may be varied identically at PVT variations. That is, a duty cycle of the output signal Vₒᵤₜ₂ of the inverter 320 may be maintained constantly.

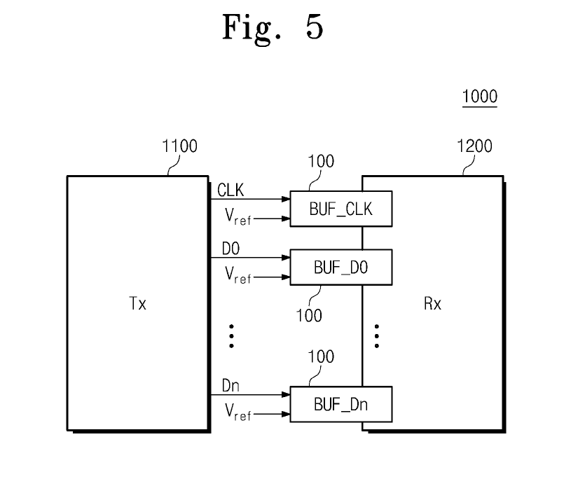

FIG. 5 is a block diagram schematically illustrating a semiconductor memory system according to an embodiment of the inventive concept.

Referring to FIG. 5, a semiconductor memory system 1000 may include a transmitter 1100 and a receiver 1200. The receiver 1200 may be a semiconductor memory device such as a DRAM, a flash memory, or the like. The transmitter 1100 may be a controller controlling the semiconductor memory device. However, the inventive concept is not limited thereto.

The transmitter 1100 may transfer a clock signal CLK and data D0 to Dn to the receiver 1200. Input buffers 100 may store the data D0 to Dn in response to the clock signal CLK to output it to the receiver 1200. That is, the receiver 1200 may use the input buffers 100 as a buffer receiving the clock signal CLK and the data D0 to Dn. That is, each of the clock signal CLK and the data D0 to Dn may correspond to a second input signal Vin provided to the input buffer 100. The input buffers 100 may be formed of an input buffer described with reference to FIG. 2, 3, or 4.

As described with reference to FIGS. 1 to 4, the input buffer 100/200/300 according to an embodiment of the inventive concept may control a characteristic variation due to PVT variations. In detail, the input buffer 100/200/300 may constantly maintain a duty cycle of an output signal Vₒᵤₜ₂ to cope with the PVT variations. Thus, the reliability of the semiconductor memory system 1000 according to an embodiment of the inventive concepts may be improved.

In example embodiments, each or all of a buffer circuit 100/200/300, a semiconductor memory device (e.g., a receiver 1200), and a semiconductor memory system 1000 may be packed by one selected from various types of packages such as PoP (Package on Package), Ball grid arrays (BGAs), Chip scale packages (CSPs), Plastic Leaded Chip Carrier (PLCC), Plastic Dual In-Line Package (PDI2P), Die in Waffle Pack, Die in Wafer Form, Chip On Board (COB), Ceramic Dual In-Line Package (CERDIP), Plastic Metric Quad Flat Pack (MQFP), Thin Quad Flatpack (TQFP), Small Outline (SOIC), Shrink Small Outline Package (SSOP), Thin Small Outline (TSOP), System In Package (SIP), Multi Chip Package (MCP), Wafer-level Fabricated Package (WFP), Wafer-Level Processed Stack Package (WSP), and the like.

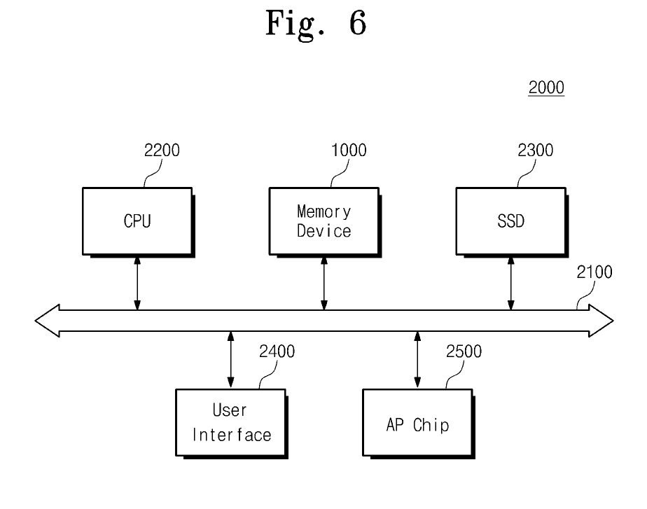

FIG. 6 is a block diagram schematically illustrating an electronic device according to an embodiment of the inventive concept.

Referring to FIG. 6, an electronic device 2000 may include a CPU 2200, a memory device 1000, a solid state drive (SSD) 2300, a user interface 2400, and an application chipset 2500.

The electronic device 2000 may be a computing system such as a notebook computer, a PC, or the like or a mobile device such as a cellular phone, a PDA, a digital camera, a portable game console, an MP3 player, or the like. However, the inventive concept is not limited thereto.

The electronic device 2000 may use a semiconductor memory system described in FIG. 5 as a memory device for temporarily storing data for an operation of the electronic device 2000.

As described above, it is possible to realize a stable operating characteristic of the electronic device 200 including a semiconductor memory system 1000 with the improved reliability.

While the inventive concept has been described with reference to exemplary embodiments, it will be apparent to those skilled in the art that various changes and modifications may be made without departing from the spirit and scope of the present invention. Therefore, it should be understood that the above embodiments are not limiting, but illustrative.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. An input buffer comprising:
an amplification circuit configured to amplify a difference between a first input signal and a second input signal; and
an inverter configured to invert an output signal of the amplification circuit,
wherein the amplification circuit provides the inverter with a bias voltage generated on the basis of one of the first and second input signals, and the inverter operates responsive to the bias voltage.

2. The input buffer of claim 1, wherein the amplification circuit comprises:
a constant current source which operates responsive to the bias voltage; and
an amplification unit which amplifies a difference between the first input signal and the second input signal.

3. The input buffer of claim 2, wherein the amplification unit comprises:
a first PMOS transistor having a source connected with a power supply voltage, a gate, and a drain;
a second PMOS transistor having a source connected with the power supply voltage, a gate, and a drain, the first and second PMOS transistors forming a current mirror;
a first NMOS transistor having a drain connected with the drain and gate of the first PMOS transistor, a gate connected to receive the first input signal, and a source connected with the constant current source; and
a second NMOS transistor having a drain connected with the drain of the second PMOS transistor, a gate connected to receive the second input signal, and a source connected with the constant current source.

4. The input buffer of claim 3, wherein the constant current source comprises:
a third NMOS transistor having a drain connected with the drains of the first and second NMOS transistor, a gate connected to receive the bias voltage, and a source grounded.

5. The input buffer of claim 4, wherein the inverter comprises:
a third PMOS transistor having a source connected with the power supply voltage, a gate connected to receive an output signal of the amplification circuit, and a drain;
a fourth NMOS transistor having a drain connected with the drain of the third PMOS transistor, a gate connected to receive the output signal of the amplification circuit, and a source; and
a fifth NMOS transistor having a drain connected with the source of the fourth NMOS transistor, a gate connected to receive the bias voltage, and a source grounded.

6. The input buffer of claim 5, wherein the gates of the third and fifth NMOS transistors are interconnected to receive the bias voltage.

7. An input buffer comprising:
an amplification circuit configured to generate a bias voltage on the basis of a first input signal or a second input signal and to amplify a difference between the first input signal and the second input signal; and
an inverter configured to invert an output signal of the amplification circuit in response to the bias voltage provided from the amplification circuit,
wherein the inverter includes pull-up and pull-down control units enabling the inverter in response to the bias voltage.

8. The input buffer of claim 7, wherein the pull-up control unit is formed of a PMOS transistor and the pull-down control unit is formed of an NMOS transistor.

9. The input buffer of claim 7, wherein the amplification circuit comprises:
first and second constant current sources configured to operate responsive to the bias voltage; and
an amplification unit configured to amplify a difference between the first input signal and the second input signal.

10. The input buffer of claim 9, wherein the first constant current source is formed of a PMOS transistor and the second constant current source is formed of an NMOS transistor.

11. The input buffer of claim 10, wherein the amplification unit comprises:
a fourth PMOS transistor having a source connected with the first constant current source, a gate connected to receive the first input signal, and a drain;
a fifth PMOS transistor having a source connected with the first constant current source, a gate connected to receive the second input signal, and a drain;
a sixth NMOS transistor having a drain connected with the drain of the fourth PMOS transistor, a gate connected to receive the first input signal, and a source connected with the second constant current source; and
a seventh NMOS transistor having a drain connected with the drain of the fifth PMOS transistor, a gate connected to receive the second input signal, and a source connected with the second constant current source.

12. The input buffer of claim 11, wherein the inverter comprises:
a sixth PMOS transistor having a source connected with a power supply voltage, a gate connected with the first constant current source, and a drain;
a seventh PMOS transistor having a source connected with the drain of the sixth PMOS transistor, a gate connected to receive the output signal of the amplification circuit;
an eighth NMOS transistor having a drain connected with the drain of the seventh PMOS transistor, a gate connected to receive the output signal of the amplification circuit, and a source; and
a ninth NMOS transistor having a drain connected with the source of the eighth NMOS transistor, a gate connected with the second constant current source, and a source grounded.

13. The input buffer of claim 11, wherein the sixth PMOS transistor generates a bias current in response to the bias voltage and the ninth NMOS transistor generates a bias current in response to the bias voltage.

14. The input buffer of claim 12, wherein the amplification unit further comprises:
an eighth PMOS transistor having a source connected with the first constant current source, a drain connected with the drain of the fourth PMOS transistor and a gate connected with the drain;
a ninth PMOS transistor having a source connected with the first constant current source, a drain connected with the drain of the fifth PMOS transistor and a gate connected with the gate of the eighth PMOS transistor;
a tenth NMOS transistor having a source connected with the second constant current source, a drain connected with the drain of the sixth NMOS transistor and a gate connected with the drain; and
an eleventh NMOS transistor having a source connected with the second constant current source, a drain connected with the drain of the seventh NMOS transistor and a gate connected with the gate of the tenth NMOS transistor.

15. A semiconductor memory system comprising:
a transmitter; and
a receiver having an input buffer configured to buffer a data signal transferred from the transmitter,
wherein the input buffer comprises:
an amplification circuit configured to amplify a difference between the data signal and a reference signal; and
an inverter configured to invert an output signal of the amplification circuit,
wherein the amplification circuit provides the inverter with a bias voltage generated on the basis of one of the data signal and the reference signal, and the inverter operates responsive to the bias voltage.

16. An input buffer comprising:
an amplification circuit configured to amplify a difference between a first input signal and a second input signal; and
an inverter configured to invert an output signal of the amplification circuit,
wherein the amplification circuit and the inverter are further configured to use a bias current having the same magnitude as a driving current.

17. The input buffer of claim 16, wherein the amplification circuit comprises:
a constant current source which provides the bias current; and
an amplification unit which amplifies a difference between the first input signal and the second input signal.

18. The input buffer of claim 17, wherein the amplification unit comprises:
a first PMOS transistor having a source connected with a power supply voltage, a gate, and a drain;
a second PMOS transistor having a source connected with the power supply voltage, a gate, and a drain, the first and second PMOS transistors forming a current mirror;
a first NMOS transistor having a drain connected with the drain and gate of the first PMOS transistor, a gate connected to receive the first input signal, and a source connected with the constant current source; and
a second NMOS transistor having a drain connected with the drain of the second PMOS transistor, a gate connected to receive the second input signal, and a source connected with the constant current source.

19. The input buffer of claim 18, wherein the constant current source comprises:
a third NMOS transistor having a drain connected with the drains of the first and second NMOS transistor, a gate connected to receive the bias voltage, and a source grounded.

20. The input buffer of claim 19, wherein the inverter comprises:
a third PMOS transistor having a source connected with the power supply voltage, a gate connected to receive an output signal of the amplification circuit, and a drain;
a fourth NMOS transistor having a drain connected with the drain of the third PMOS transistor, a gate connected to receive the output signal of the amplification circuit, and a source; and
a fifth NMOS transistor having a drain connected with the source of the fourth NMOS transistor, a gate connected to receive the bias voltage, and a source grounded.
